(19) United States
(12) Patent Application Publication
(10) Pub. No.: US 2007/0292697 A1
(43) Pub. Date: Dec. 20, 2007

(54) Metal Base Circuit Substrate For An Optical Device And Method Manufacturing The Aforementioned Substrate

(75) Inventors: Kazumi Nakayoshi, Chiba (JP); Katsutoshi Mine, Chiba (JP); Akihiko Kobayashi, Chiba (JP)

Correspondence Address: HOWARD & HOWARD ATTORNEYS, P.C., THE PINEHURST OFFICE CENTER, SUITE #101, 39400 WOODWARD AVENUE, BLOOMFIELD HILLS, MI, 48304-5151, US

(73) Assignee: DOW CORNING TORAY COMPANY, LTD., Chiyoda-ku, Tokyo, JP (JP)

(21) Appl. No.: 10/598,967

(22) PCT Filed: Mar. 8, 2005
(86) PCT No.: PCT/JP05/04413

§ 371 Date: Jul. 11, 2007

(30) Foreign Application Priority Data
Mar. 17, 2004 (JP) JP2004-076313

(51) Int. Cl. H01L 33/00

(52) U.S. Cl. 428/450; 427/108

(57) ABSTRACT

A metal base circuit substrate for an optical device, which effectively reflects the generated light and radiates heat from the substrate, comprises a metal base substrate made from aluminum or aluminum alloy that supports an electric circuit via an insulation layer, wherein the insulation layer is formed from a transparent cross-linked silicone body, and the electric circuit is formed directly on the insulation layer. And an efficient method for manufacturing the aforementioned substrate comprises the steps of: a) applying a cross-linkable silicone onto the surface of a metal base substrate made from aluminum or aluminum alloy, b) cross-link

### TECHNICAL FIELD

The present invention relates to a metal base circuit substrate for an optical device and to a method of manufacturing the aforementioned substrate. More particularly, the invention concerns a metal base circuit substrate that is suitable for use in conjunction with an LED module or a similar optical device and that effectively reflects the generated light and radiates heat from the aforementioned substrate. The invention also concerns an effective method for manufacturing a substrate that possesses aforementioned properties.

### BACKGROUND ART

Ever growing increase in a degree of integration, density, and operation frequencies of electronic devices stimulated studies aimed at the development of circuit substrates capable of effectively removing the heat, generated by such devices during operation, via radiation. For effective radiation, it is necessary to solve some problems, such as decrease of thermal resistance in the material from which the circuit substrates are made, decrease of thermal resistance between the materials of the circuit substrate and insulation, and decrease of thermal resistance between the materials of insulation and electrodes. For example, it has been proposed to solve the above problems by forming an insulation layer of thermoplastic or thermosetting resin that contains a filler of high thermal conductivity on the surface of a base substrate made from a metal of high thermal conductivity, e.g., copper or aluminum, and then forming circuit elements on the insulation layer from a metal foil by hot pressing (see Japanese Laid-Open Patent Application Publication (Kokai) (hereinafter referred to as “Kokai”) Hei 7-320538, Kokai Hei 8-264912, Kokai 2002-322372, and Kokai 2003-229508). On the other hand, in order to improve stress-relaxation properties of the circuit substrate, it was proposed to produce a metal base circuit substrate with circuit elements applied onto the metal base substrate through an insulation layer of a laminated structure having a number of rubber-composition and resin-composition sublayers (see Kokai Hei 11-150345).

However, the metal base circuit substrates of the aforementioned type still appeared to be unsuitable for use in conjunction with optical devices such as, e.g., LED modules, since substrates for supporting such modules should be able to effectively reflect light generated by the LED and remove the heat, generated by the LED, via radiation.

It is an object of the present invention to provide a metal base circuit substrate that is suitable for use in conjunction with an optical device such as an LED module as it is able to effectively reflect light and remove via radiation the heat generated by the LED. Another object is to provide a method of effectively manufacturing the aforementioned metal base circuit substrate.

### DISCLOSURE OF INVENTION

A metal base circuit substrate for an optical device made according to the present invention comprises a metal base substrate of aluminum or aluminum alloy that supports an electric circuit via an insulation layer, wherein the insulation layer is formed from a transparent cross-linked silicone body, and the electric circuit is formed directly on the insulation layer.

A method of the invention for manufacturing a metal base circuit substrate for an optical device comprises the steps of:
a) applying a cross-linkable silicone onto the surface of a metal base substrate made from aluminum or aluminum alloy,
b) cross-linking the silicone, thereby forming an insulation layer from the transparent cross-linked silicone body, and then
c) forming an electric circuit directly on said insulation layer either by (i) forming a conductive layer by electrolytic or non-electrolytic plating with subsequent etching, or (ii) by printing with a conductive ink.

### EFFECTS OF INVENTION

The metal base circuit substrate of the invention for supporting an optical device is able to efficiently reflect the light and remove via radiation the heat generated by the aforementioned optical device e.g., an LED module, during the device operation. The invention also allows effective manufacturing of the aforementioned metal base circuit substrate.

### BRIEF DESCRIPTION OF THE DRAWINGS

FIG. 1 is a sectional view of a metal base circuit substrate of the invention for use in conjunction with an optical device.

FIG. 2 is a sectional view of a metal base circuit substrate for use in conjunction with an optical device in accordance with another embodiment of the invention.

### REFERENCE NUMBERS

1 metal base substrate
2 insulation layer 1
3 circuits
4 insulation layer 2

### DETAILED DESCRIPTION OF THE INVENTION

First, a more detailed explanation is given to the metal base circuit substrate of the invention for supporting an optical device.

A metal base substrate used in the circuit substrate of the invention is made of aluminum or aluminum alloy. These materials are most suitable for circuit substrates of mobile devices in view of their excellent machinability, low cost, and low weight. Furthermore, since aluminum has high reflectivity of light in the range from ultraviolet to visible light, it may provide high external radiation, even in the case of concave mirrors. Therefore, aluminum is suitable for use in conjunction not only with lens-type LED modules but also with reflection-type LED modules that are characterized by high luminous intensity. Aluminum has high reflectivity also with regard to light in the ultraviolet range of the spectrum. Therefore, aluminum base substrates are also suitable for use in conjunction with lens-type LED modules that employs ultraviolet-ray light-emitting elements or with reflection-type ultraviolet-ray LED modules. There are no restrictions with regard to the thickness of metal base substrates, but it is recommended that they have a thickness of 0.15 to 5.0 mm, preferably 0.5 to 3.0 mm.

An insulation layer of the circuit substrate of the invention is comprised of a transparent cross-linked silicone. A cross-linkable silicone suitable for the formation of the insulation layer may be represented by silicones cross-linkable due to an addition reaction, condensation reaction, or under effect of ultraviolet radiation. Since such silicones may form cross-linked silicone bodies of high hardness, they can be used for forming cross-linkable resins. Such a cross-linkable resin may be exemplified by a silicon-bonded hydrogen atom-containing silsesquioxane, DT-type silicone resin consisting of bi-functional siloxane units and tri-functional siloxane units. In order to improve adhesive properties and adhesion to the metal base substrates, the cross-linkable siloxane may be combined with a coupling agent, such as a silane coupling agent, titanium coupling agent, etc.

There are no special restrictions with regard to light transmission through the cross-linked silicone body that constitutes an insulation layer, provided that this body is transparent through its entire thickness. It is recommended, however, that within the range of light spectrum from ultraviolet to visible, e.g., at a wavelength of 380 nm, light transmission through the cross-linked silicone body be not less than 80%, preferably not less than 90%. At this condition, the circuit substrate of the invention becomes suitable for use with an LED module, since the light emitted from the LED will be efficiently reflected by the metal base circuit substrate. Furthermore, there are no special restrictions with regard to the dielectric constant of the cross-linked silicone body, but since with an increase in operation frequencies of electronic devices it becomes more difficult to delay a signal, it is recommended that the dielectric constant be not more than 4.0, preferably not more than 3.5, and more preferably not more than 3.0. There are no restrictions also with regard to hardness of the cross-linked silicone body, but in general the pencil hardness should be not less than 2H as specified by JIS K 5600-5-4: 1999 “Testing Methods for Paints—Scratching Hardness (Pencil Hardness Method)”.

There are no special restrictions with regard to the thickness of the insulation layer. However, in order to provide both satisfactory insulation properties and satisfactory heat-radiation properties, the thickness should not exceed 10 μm and preferably should be between 1 and 5 μm. If the insulation layer is too thin, it will be difficult to improve adhesion of circuit elements. On the other hand, if the insulation layer is too thick, this will impair radiation properties of the circuit substrate.

One distinguishing feature of the circuit substrate of the invention is that the electric circuit is formed directly on the insulation layer. Such an approach makes it possible to reduce thermal resistance between the circuit elements and insulation layer. The electric circuit may be formed directly on the insulation layer, e.g., by forming a conductive layer on the surface of the insulation layer by electrolytic or non-electrolytic plating with subsequent etching, or by printing conductive elements on the insulation layer with the use of a conductive ink.

If necessary, for protection against corrosion and for improving moisture-resistant properties of the circuit substrate, the circuit elements can be coated with another transparent insulation layer. There are no special restrictions with regard to the thickness of this insulation layer. This layer may be cross-linked, non-cross-linked, elastomeric, or rigid. There are no special restrictions also with regard to a material from which this insulation layer can be made. For example, this layer can be made from the same cross-linkable silicone as the first-mentioned insulation layer. Furthermore, for protection from corrosion and damage, the side of the circuit substrate that does not have the insulation layer also may be coated with a protective film. If it is required, the protective film can be removed when necessary.

The following is a more detailed description of the method for manufacturing a metal base circuit substrate of the invention for supporting an optical device.

According to this method, the surface of a metal base substrate made from aluminum or aluminum alloy is first coated with a cross-linkable silicone. The cross-linkable silicone may be one of those mentioned above. There are no special restrictions with regard to a silicone application procedure, and any suitable method known in the art can be used for this operation. For example, spin coating can be used for obtaining a coating film having a uniform thickness.

In the next step, the applied layer is cross-linked to form a transparent cross-linked silicone body that constitutes an insulation layer. There are no special restrictions with regard to a cross-linking procedure, but in case of cross-linking with heating, it is recommended that the process temperature be within the range of 150° C. to 250° C.

As has been mentioned above, circuit elements can be formed directly on the insulation layer (i) by electrolytic or non-electrolytic plating with subsequent etching, or (ii) by printing conductive elements on the insulation layer with the use of a conductive ink.

Process (i) can be carried out by electrolytic, non-electrolytic, vacuum, or melt plating. Non-electrolytic plating is more preferable and may be carried out by forming a layer of silver, copper, or another conductive material directly on the insulation layer, or by first forming an underlayer for a conductive layer by non-electrolytic plating, forming a conductive layer of silver, copper, etc., on the aforementioned underlayer by electrolytic plating, and then creating a pattern by a known method such as etching.

Process (ii) is formation of conductive elements by stencil, mesh, or screen printing, or by an image transfer method, or ink-jetting. Such methods also allow formation of printing elements directly on the insulation layer.

As has been mentioned above, for protection against corrosion or damage, the circuit elements, as well as the surface of the metal base substrate that is free of the aforementioned insulation layer, can be coated with a protective film. There are no special restrictions with regard to the material from which this protective film can be made. For example it can be made from the same cross-linkable silicone as described above.

### EXAMPLES

The metal base circuit substrate of the invention for supporting an optical element and a method of manufacturing such a substrate will be further described in more detail with reference to practical and comparative examples. Criteria that were used for evaluating the base circuit substrate of the invention for supporting an optical element are described below.

[Pencil Hardness]

A cross-linkable silicone was applied onto an aluminum substrate by a method described in the subsequent practical examples, the applied layer was cross-linked under appropriate conditions to form a transparent body of a cross-linked silicone, and then pencil hardness of the obtained cross-linked layer was measured in accordance with JIS K 5600-5-4: 1999 “Testing Methods for Paints—Scratching Hardness (Pencil Hardness Method)”.

[Thermal Conductivity]

Samples having size of 10 mm by 10 mm were cut out from metal base circuit substrates produced in practical and comparative examples, and then thermal resistance was measured with the use of a conductive grease (SC102, trade name of Dow Corning Toray Silicone Co., Ltd.) by means of a resin thermal resistance tester (a product of Hitachi Seisakusho Co., Ltd.). Thermal conductivity of a metal base circuit substrate was determined on the basis of the corrected value of the thermal resistance measured by the aforementioned tester for the aforementioned conductive grease.

[Dielectric Constant, Insulation Breakdown Strength]

Aluminum substrates were coated with the cross-linkable silicone in the same manner as in practical examples, and transparent bodies of silicone were made by cross-linking the material of the coating under appropriate conditions. Dielectric constants of the cross-linked coatings were measured at 1 MHz. The insulation breakdown strength of the cross-linked coating was determined by measuring the insulation breakdown voltage.

[Light Transmission]

Transparent glass plates were coated with cross-linkable silicones produced in the practical examples, and then transparent bodies of silicone were formed by cross-linking the material of the coatings under appropriate conditions. Light transmission through the cross-linked silicone coatings was measured with a spectrophotometer (at 380 μm wavelength).

[Reflectance]

The metal base circuit substrates were illuminated with light (having a wavelength within the range of 280 to 800 nm), and the initial reflectance were measured with the use of a spectroreflectometer. The same measurements were carried out after the substrates had been aged by heat treating for 1000 hours at 150° C.

[Luminous Efficiency]

Pseudo-white LED's were installed on the metal base circuit substrates, and the initial reflectance were measured at wavelengths of 270 to 800 nm. The same measurements were carried out at wavelengths of 270 to 800 nm after the LED-supporting substrates had been aged by heat treatment for 1000 hours at 150° C.

### Practical Example 1

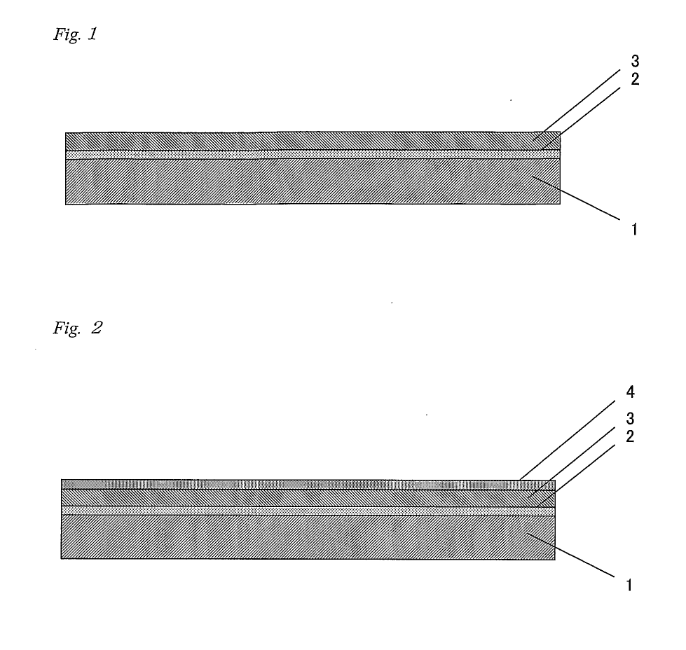

A metal base circuit substrate shown in FIG. 1 was manufactured as described below.

A cross-linkable silicone resin solution (trade name AY42-170 of Dow Corning Toray Silicone Co., Ltd.) was applied dropwise onto a 3 mm-thick, 100 mm-long, and 100 mm-wide aluminum substrate, and then the coating was made by spinning the applied solution (initial frequency of rotation: 500 rpm; main frequency of rotation: 2000 rpm). The coated unit was heat treated for 30 min. at 150° C. in a hot-air-circulation oven. As a result, an insulation layer 1 was formed on the aluminum substrate in the form of a transparent body of cross-linked silicone.

A silver complex in an ammonia aqueous solution of a silver nitrate was prepared, and then the aluminum substrate was subjected to non-electrolytic plating using a 10% solution of potassium sodium tartarate as a reduction solution. The obtained silver-plated layer on the aluminum substrate was subjected to etching with an aqueous solution of ferric chloride, whereby 5 μm-thick silver circuit elements were formed. Characteristics of the obtained aluminum base circuit substrate were measured. Results of measurements are shown in Table 1.

### Practical Examples 2

A metal base circuit substrate shown in FIG. 1 was manufactured as described below.

A cross-linkable silicon-bonded hydrogen atom-containing silsesquioxane resin solution (trade name FOx of Dow Corning Corp.) was applied dropwise onto a 3 mm-thick, 100 mm-long, and 100 mm-wide aluminum substrate, and then the coating was made by spinning the applied solution (frequency of rotation: 2000 rpm). The coated unit was heat treated for 30 min. at 250° C. in a hot-air-circulation oven. As a result, an insulation layer 1 was formed on the aluminum substrate in the form of a transparent body of cross-linked silicone.

A thermally cross-linkable silicone-type conductive adhesive agent (with a silver filler) was applied by stencil printing onto the insulation layer 1 of the aluminum substrate to form a desired circuit pattern. The applied layer was then cured by 30 min. heat treatment at 150° C. in a hot-air-circulation oven. The circuit elements were 10 μm thick.

Characteristics of the obtained aluminum base circuit substrate were measured. Results of measurements are shown in Table 1.

### Practical Example 3

A metal base circuit substrate shown in FIG. 2 was manufactured as described below.

A cross-linkable silicone resin solution (trade name SR2510 of Dow Corning Toray Silicone Co., Ltd.) was applied dropwise onto a 3 mm-thick, 100 mm-long, and 100 mm-wide aluminum substrate, and then the coating was made by spinning the applied solution (frequency of rotation: 1500 rpm). The coated unit was heat treated for 30 min. at 150° C. in a hot-air-circulation oven. As a result, an insulation layer 1 was formed on the aluminum substrate in the form of a transparent body of cross-linked silicone.

A silver complex in an ammonia aqueous solution of a silver nitrate was prepared, and then the aluminum substrate was subjected to non-electrolytic plating using a 10% solution of potassium sodium tartarate as a reducing solution. The obtained silver-plated layer on the aluminum substrate was subjected to etching with an aqueous solution of ferric chloride, whereby 5 μm-thick silver circuit elements were formed. The insulation layer 1 and the silver circuit element were coated with a cross-linkable silicone resin solution (trade name AY42-170 of Dow Corning Toray Silicone Co., Ltd.), and the coated unit was heat treated for 30 min. at 150° C. in a hot-air-circulation oven. As a result, an insulation layer 2 was formed on the aluminum substrate in the form of a transparent body of cross-linked silicone.

### Comparative Example 1

A metal base circuit substrate was manufactured as described below.

An alumina-containing insulation silicone-type adhesive with radiation properties (trade name SE4450 of Dow Corning Toray Silicone Co., Ltd.) was applied onto a 3 mm-thick, 100 mm-long, and 100 mm-wide aluminum substrate. A 35 μm thick copper foil was applied onto the adhesive layer, and the unit was heat treated for 1 hour in an oven at 150C, whereby the copper foil was attached via adhesion.

The copper foil was subjected to etching with an aqueous solution of ferric chloride, whereby 35 μm-thick copper circuit elements were formed. Characteristics of the obtained aluminum base circuit substrate were measured. Results of measurements are shown in Table 1. The alumina-containing insulation silicone-type adhesive with radiation properties had an ashy color, and the index of reflection was extremely low.

### Comparative Example 2

A metal base circuit substrate was manufactured as described below.

A bisphenol-A type resin composition was prepared by mixing 100 parts by weight of Epikote 828 (the product of Japan Epoxy Resin Co., Ltd.), 30 parts by weight of Epikure 113 (the product of Japan Epoxy Resin Co., Ltd.), and a minute quantity of silica.

The prepared epoxy resin composition was applied onto an aluminum substrate, and then 35 μm-thick copper foil was applied onto the coating. The unit was heated for 1 hour at 180° C., whereby the copper foil was attached via adhesion.

The copper foil on the aluminum substrate was subjected to etching with an aqueous solution of ferric chloride, whereby 35 μm-thick copper circuit elements were formed. Characteristics of the obtained aluminum base circuit substrate were measured. Results of measurements are shown in Table 1. The obtained aluminum base circuit substrate was subjected to high-temperature aging that noticeably impaired insulation properties of the substrate and conductive properties of the circuit elements.

TABLE 1

| | Examples | | | | |
|---|---|---|---|---|---|
| | | | | Comparative | |
| | Present Invention | | | Example | |
| | Pr. Ex. | Pr. Ex. | Pr. Ex. | Comp. | Comp. |
| Properties | 1 | 2 | 3 | Ex. 1 | Ex. 2 |
| Thickness of insulation layer 1 (μm) | 2 | 8 | 8 | 50 | 80 |
| Pencil hardness of insulation layer 1 (-) | 3H | 4H | 3H | — | — |
| Dielectric constant (-) | 3.0 | 3.0 | 3.0 | 4.7 | 3.7 |
| Thermal conductivity (W/mK) | 4 | 3 | 3 | 3.5 | 3 |
| Insulation breakdown strength (V/μm) | 700 | 800 | 800 | 24* | 40* |
| Light transmission through insulation | 100 | 98 | 98 | 0 | 65 |
| layer 1 (%) | | | | | |
| Reflectance of the substrate (%) | | | | | |
| initial | 95 | 95 | 95 | 0 | 60 |
| after high-temperature aging | 95 | 95 | 85 | 0 | 20 |
| Luminescent efficiency (lm/W) | | | | | |
| initial | 30 | 30 | 30 | 10 | 25 |
| after high-temperature aging | 29 | 28 | 28 | 5 | 15 |

### INDUSTRIAL APPLICABILITY

Since the metal base circuit substrate of the invention for use in conjunction with an optical device comprises a metal base substrate of aluminum or aluminum alloy and an insulation layer of a transparent cross-linked silicone body, the substrate is characterized by excellent radiation properties and has improved illumination efficiency for the light emitted by the light-generating element. In view of the above, the substrate of the invention is suitable for used as a metal base circuit substrate for an LED module.

1. A metal base circuit substrate for an optical device comprising a metal base substrate made from aluminum or aluminum alloy that supports an electric circuit via an insulation layer, wherein said insulation layer is formed from a transparent cross-linked silicone body, and said electric circuit is formed directly on said insulation layer.

2. The metal base circuit substrate for an optical device according to claim 1, wherein said insulation layer has a thickness not exceeding 10 μm.

3. The metal base circuit substrate for an optical device according to claim 1, wherein a dielectric constant of said cross-linked silicone body does not exceed 4.0.

4. The metal base circuit substrate for an optical device according to claim 1, wherein said circuit is formed either by etching a conductive layer formed in said insulation layer by electrolytic or non-electrolytic plating, or by printing said circuit on said insulation layer with the use of an electroconductive ink.

5. A method of manufacturing a metal base circuit substrate for an optical device comprising the steps of:
a) applying a cross-linkable silicone onto the surface of a metal base substrate made from aluminum or aluminum alloy,
b) cross-linking said silicone, thereby forming an insulation layer from the transparent cross-linked silicone body; and then
c) forming an electric circuit directly on said insulation layer either by (i) forming a conductive layer by electrolytic or non-electrolytic plating with subsequent etching, or (ii) by printing with a conductive ink.
